(19) United States
(12) Patent Application Publication
(10) Pub. No.: US 2010/0275968 A1
(43) Pub. Date: Nov. 4, 2010

(54) SOLAR POWER SYSTEMS OPTIMIZED FOR USE IN COLD WEATHER CONDITIONS

(75) Inventors: Fredrick Kaiser, Bellingham, WA (US); Thanh Le, Ferndale, WA (US); Darren Hoppins, Ferndale, WA (US)

Correspondence Address: SCHACHT LAW OFFICE, INC., SUITE 202, 2801 MERIDIAN STREET, BELLINGHAM, WA, 98225-2412, US

(73) Assignee: Alpha Technologies Inc., Bellingham, WA (US)

(21) Appl. No.: 12/770,278

(22) Filed: Apr. 29, 2010

Related U.S. Application Data
(63) Continuation of application No. PCT/US10/32832, filed on Apr. 28, 2010.
(60) Provisional application No. 61/174,925, filed on May 1, 2009.

(51) Int. Cl. H01L 31/042

(52) U.S. Cl. 136/244

(57) ABSTRACT

A solar power system for supplying electrical energy to a load based on solar energy comprising at least one solar panel, a power supply, and at least one mode select switch. The at least one solar panel comprises at least one solar cell. The at least one mode select switch is operatively connected to the at least one solar panel, the power supply, and the load. The at least one mode select switch is operable in a first mode and in a second mode. In the first mode, the at least one solar cell is capable of supplying electrical energy to the load. In the second mode, the power supply supplies electrical energy to the at least one solar cell such that the at least one solar cell generates heat.

### RELATED APPLICATIONS

This application (Attorney's Ref. No. P216410) claims priority of U.S. Provisional Patent Application Ser. No. 61/174,925, filed May 1, 2009, and this application (Attorney's Ref. No. P216410) is a continuation of International Patent Application No. PCT/US10/32832, filed Apr. 28, 2010. The entire contents of both related applications are incorporated herein by reference.

### TECHNICAL FIELD

The present invention relates to the generation of electricity using solar panels and, more specifically, to systems and methods for allowing solar panels to operate with optimized efficiency in cold weather conditions.

### BACKGROUND

Solar panels convert solar energy into electricity. A solar panel typically comprises one or more solar cells mounted within a panel structure. Typically, the panel structure defines a panel surface configured such that sunlight reaches the solar cells supported by the panel structure. To maximize insolation levels at the solar cells, sunlight should pass substantially unobstructed through the panel surface.

Weather conditions can reduce the efficiency of a solar panel by reducing the amount of sunlight that reaches the panel surface. For example, clouds can reduce insolation levels at the panel surface. The present invention is of particular significance in the context of cold weather conditions that reduce insolation levels and thus interfere with the conversion of solar energy into electricity.

### SUMMARY

The present invention may be embodied as a solar power system for supplying electrical energy to a load based on solar energy comprising at least one solar panel, a power supply, and at least one mode select switch. The at least one solar panel comprises at least one solar cell. The at least one mode select switch is operatively connected to the at least one solar panel, the power supply, and the load. The at least one mode select switch is operable in a first mode and in a second mode. In the first mode, the at least one solar cell is capable of supplying electrical energy to the load. In the second mode, the power supply supplies electrical energy to the at least one solar cell such that the at least one solar cell generates heat.

The present invention may also be embodied as a method of supplying electrical energy to a load based on solar energy comprising the following steps. At least one solar panel comprising at least one solar cell is provided. A power supply is provided. At least one mode select switch is operatively connected to the at least one solar panel, the power supply, and the load. The at least one mode select switch is operable in a first mode in which the at least one solar cell is capable of supplying electrical energy to the load. The at least one mode select switch is also operable in a second mode in which the power supply supplies electrical energy to the at least one solar cell such that the at least one solar cell generates heat.

The present invention may also be embodied as a solar power system for supplying electrical energy to a load based on solar energy comprising at least one solar panel, a temperature sensor, an insolation sensor, a current supply, and at least one mode select switch. The at least one solar panel comprises at least one solar cell comprising at least one resistive element. The temperature sensor generates temperature data indicative of a temperature of the at least one solar panel. The insolation sensor generates insolation data indicative of an insolation level associated with the at least one solar panel. The at least one mode select switch is operatively connected to the at least one solar panel, the current supply, and the load. The at least one mode select switch is operable in a first mode and in a second mode. In the first mode, the at least one solar cell is capable of supplying electrical energy to the load. In the second mode, the current supply supplies current to the at least one resistive element of the at least one solar cell at least in part on the temperature data and the insolation data such that the at least one solar cell generates heat.

### BRIEF DESCRIPTION OF DRAWINGS

FIG. 1 is a block diagram of a first example solar panel system of the present invention;

FIG. 2 is a block diagram depicting the first example solar panel system in a power generating mode;

FIG. 3 is a block diagram depicting the first example solar panel system in a heating mode;

FIG. 4 is a perspective view of a typical installation of a solar panel system;

FIG. 5 is a top plan view of a portion of the solar panel installation depicted in FIG. 4;

FIG. 6 is a side elevation view of the solar panel installation depicted in FIG. 4;

FIG. 7 is a side elevation view of the solar panel installation depicted in FIG. 4 illustrating an obstruction thereon;

FIG. 8 is a side elevation view of the solar panel installation depicted in FIG. 4 after the obstruction of FIG. 7 has been removed;

FIG. 9 is a first simplified circuit diagram illustrating a control system that may be used when operating a solar panel system of the present invention in a heating mode;

FIG. 10 is second simplified circuit diagram illustrating a control system that may be used when operating a solar panel system of the present invention in a heating mode;

FIG. 11 is a block diagram of another example solar panel system of the present invention, where the solar panel system employs a plurality of photovoltaic panels arranged in series;

FIG. 12 is a block diagram of another example solar panel system of the present invention, where the solar panel system employs a plurality of groups of series-connected photovoltaic panels, in which the groups of photovoltaic panels are arranged in parallel;

FIG. 13 is a block diagram of another example solar panel system of the present invention, where the solar panel system employs a plurality of groups of series-connected photovoltaic panels, in which the groups of photovoltaic panels are arranged in parallel and each group may be heated independently;

FIG. 14 is a block diagram of another example solar panel system of the present invention, where the solar panel system employs a plurality of groups of series-connected photovoltaic panels, in which the groups of photovoltaic panels are arranged in parallel, each group may be heated independently, and power from one group may be applied to a power processor;

FIG. 15 is a block diagram of another example solar panel system of the present invention, where the solar panel system employs a plurality of groups of series-connected photovoltaic panels, in which the groups of photovoltaic panels are arranged in parallel, each group may be heated independently, and power from one group or from a battery may be applied to a power processor;

FIG. 16 is a block diagram of another example solar panel system of the present invention, where the solar panel system employs a plurality of groups of series-connected photovoltaic panels, in which the groups of photovoltaic panels are arranged in parallel and each group may be heated independently, the system further comprising a controller, insolation sensor, and a communications port;

FIG. 17 is a block diagram of another example solar panel system of the present invention, where the solar panel system employs a plurality of photovoltaic panels arranged in series and a controller may operate a panel motor to execute a mechanical clear operation;

FIG. 18 is a top plan view of another example solar panel installation comprising a vibrational device for executing a mechanical clear operation of obstructions on a photovoltaic panel;

FIG. 19 is a side elevation view taken along lines 19-19 in FIG. 18;

FIGS. 20 and 21 are side elevation views of another example solar panel installation comprising a tilting device for executing a mechanical clear operation of obstructions on a photovoltaic panel;

FIGS. 22 and 23 are side elevation views of another example solar panel installation comprising a weight sensor for sensing a weight of a photovoltaic panel, including the weight of any obstruction thereon;

FIG. 24 is a top plan view of another example solar panel installation comprising a wiper system for executing a mechanical clear operation of obstructions on a photovoltaic panel;

FIG. 25-28 are flow charts depicting example logic sequences that may be implemented by a solar panel system of the present invention; and

FIGS. 29-31 are flow charts depicting example functions that may be called by the logic sequences of FIGS. 25-28;

### DETAILED DESCRIPTION

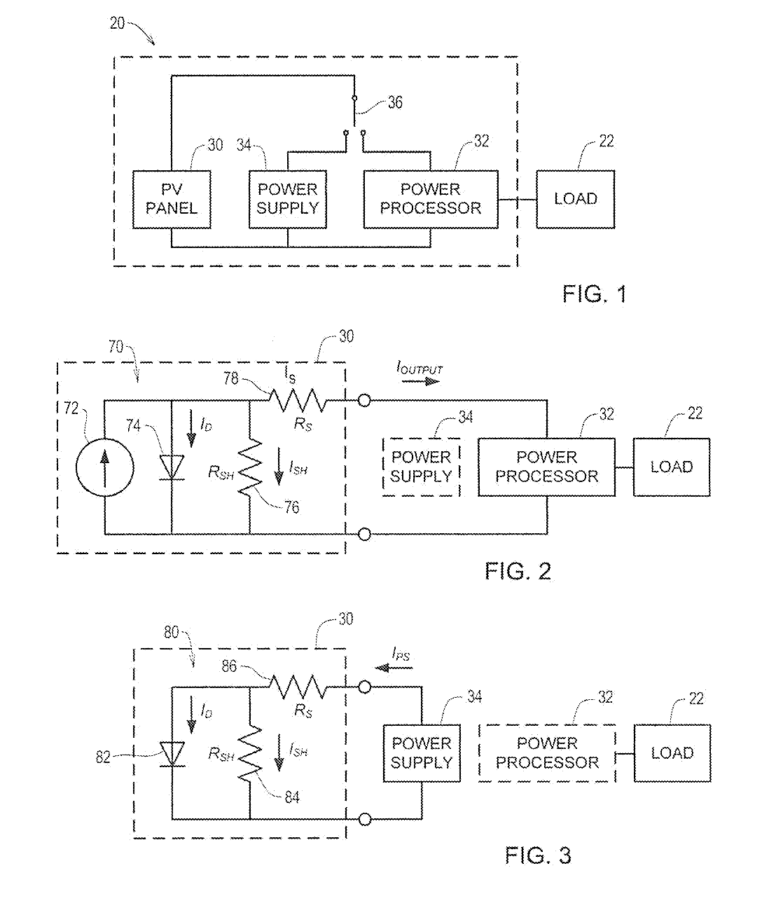

Referring initially to FIG. 1 of the drawing, depicted therein is a block diagram of an example solar power system 20 constructed in accordance with, and embodying, the principles of the present invention. The example solar power system 20 is configured to provide power to a load 22. The load 22 may be any electrical equipment capable of using electrical power output from the solar power system 20; typically, the load will be electronics such as household appliances and/or telecommunications equipment such as telephony or CATV equipment. Additionally, the load may be or comprise energy storage components such as a battery or may be the utility power grid that allows power generated by the system 20 to be used at a location remote from the system 20.

As shown in FIG. 1, the example solar power system 20 comprises at least one photovoltaic panel 30, a power processor 32, a power supply 34, and a switch 36. The panel 30, power processor 32, and switch 36 are or may be conventional and will not be described herein in further detail except that extent helpful to understand the construction and operation of the solar power system 20 of the present invention.

The example switch 36 is a single pole, double throw switch, or the electrical equivalent thereof, that allows the system 20 to be placed in a power generating mode as illustrated in FIG. 2 and a heating mode as illustrated in FIG. 3. In the power generating mode, the photovoltaic panel 30 is operatively connected to the power processor 32 to provide power to the load 22; the switch 36 effectively removes the power supply 34 from the system 20 when the system 20 is in the power generating mode. In the heating mode, the switch 36 effectively removes the power processor 32 from the system 20 and connects the power supply 34 to the panel 30. In this heating mode, the power supply 34 provides power to the panel 30 to increase the temperature of the panel 30.

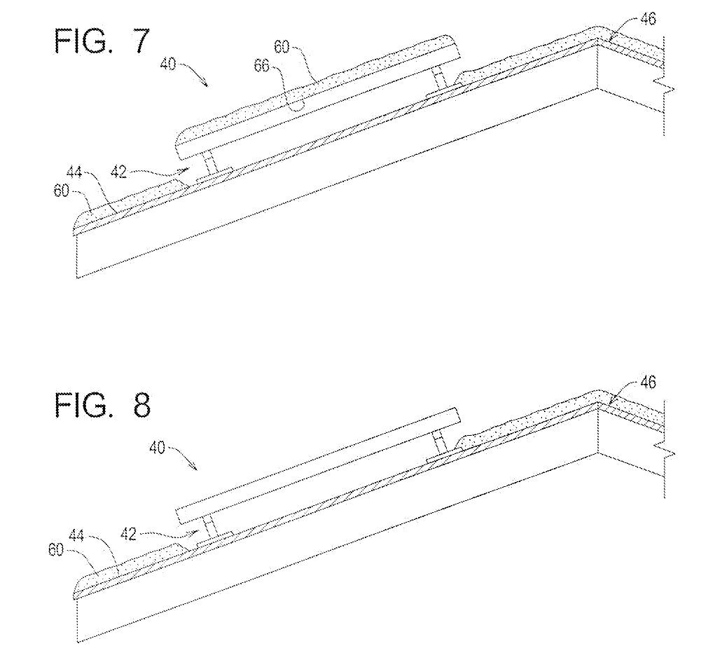

When inclement or cold weather conditions are present that suggest that an obstruction, such as snow, ice, and/or frost, is present on the panels 30, the switch 36 is operated to place the system 20 in the heating mode. In this heating mode, the temperature of the panel 30 is increased to melt at least a portion of the obstruction 60 on the panels 30 (FIGS. 7 and 8).

When the obstruction 60 has been at least partly removed, the system 20 is returned to the power generating mode. The system 20 operates more efficiently in the power generating mode with the obstruction 60 at least partly removed than with the obstruction 60 in place.

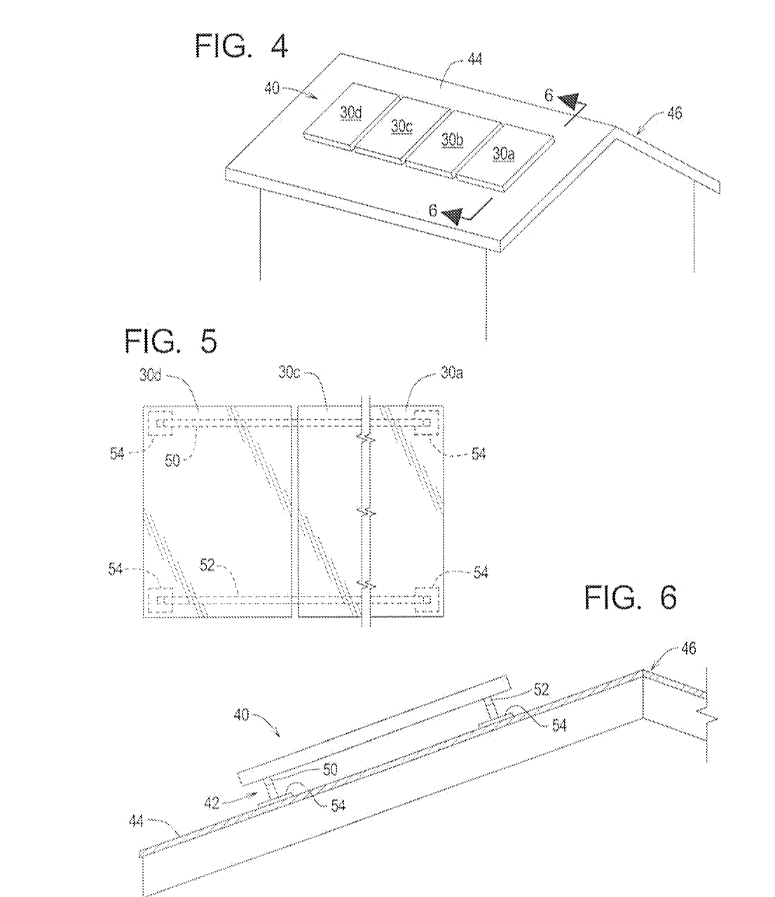

Referring now for a moment to FIGS. 4-6, depicted therein is a typical solar panel installation 40. The example solar panel installation 40 comprises four photovoltaic panels 30a, 30b, 30c, and 30d. The photovoltaic panels 30 are supported by a mounting structure 42 on a mounting surface 44 of a structure 46. The example structure 46 is a dwelling, and the example mounting surface 44 is a roof, but the panels 30 may be supported on other mounting surfaces and structures.

As shown in FIGS. 5 and 6, the example mounting structure 42 comprises first and second rails 50 and 52 and a plurality of rail brackets 54. The rail brackets 54 are rigidly mounted onto the mounting surface 44, and the rails 50 and 52 are rigidly mounted onto the rail brackets 54. The rails 50 and 52 support at least one of the panels 30 and conventionally support a plurality of the panels 30 as shown in FIGS. 4 and 5. The details of construction and installation of the example rails 50 and 52 and example brackets 54 are or may be conventional and will not be described herein in detail. In addition, mounting systems other than the example rail-type mounting system 42 may be used to support the panels 30 relative to a structure, depending upon the details of the particular installation.

Turning now to FIGS. 7 and 8, it can be seen that the panels 30 have been subjected to cold weather and an obstruction 60 is present on the panels 30 and the mounting surface 44. In FIG. 7, the obstruction 60 on the panels 30 is depicted as snow. In addition, cold weather may result in ice (e.g., from freezing rain or melting snow) or frost being deposited on the panels 30 and forming the obstruction 60. In any case, cold weather obstructions such as snow, ice, and/or frost may inhibit or prevent sunlight from reaching the panels 30, at a minimum reducing the efficiency of the solar power system 30.

If the obstruction 60 is formed by frost, heat alone may entirely eliminate the obstruction 60 as shown in FIG. 8. If the obstruction 60 is formed by ice, snow, or any combination of ice, snow, and frost, operating the system 20 in the heating mode may heat a boundary layer 62 of the obstruction 60 adjacent to the panel 30. The boundary layer 62 may allow at least a part of the obstruction 60 to slide off of or otherwise fall from the panel 30.

Referring for a moment back to FIGS. 2 and 3, the operation of the system 20 in the power generating and heating modes will now be described in further detail. In the power generating mode, the panel 30 and power processor 32 operate in a conventional manner. FIG. 2 illustrates that the photovoltaic panel or panels 30 comprise a plurality of solar cells that may be modeled as an equivalent circuit 70 comprising a current source 72, a diode 74 in parallel with the current source 72, a shunt resistance 76 in parallel with the diode 74 and current source 72, and a series resistance 78. Current flowing out of the current source 70 flows through the diode 74 (I_{D}), through the shunt resistance 76 (I_{SH}), and through the series resistance 78 (I_{S}). The current I_{S} flowing through the series resistance 78 of the equivalent circuit 70 forms the output current I_{OUTPUT} of the panel 30, while the current flowing through the shunt resistance 76 defines the output voltage of the panel 30.

In the heating mode, the equivalent circuit 80 of the panel 30 is shown in FIG. 3. The equivalent circuit 80 comprises a diode 82, a shunt resistance 84, and a series resistance 86. In this case, current flowing from the power supply 34 (I_{PS}) flows through the series resistance 86 and then divides between the diode 82 (I_{D}) and the shunt resistance 84 (I_{SH}). The current I_{PS} flowing through the series resistance 86 and current I_{SH} flowing through the shunt resistance 84 generate heat. The heat generated by the current flowing through the resistances 84 and 86 warms the panel 30. Heat within the panel 30 is transferred to the obstruction 60 to warm the boundary layer 62 thereof as generally described above.

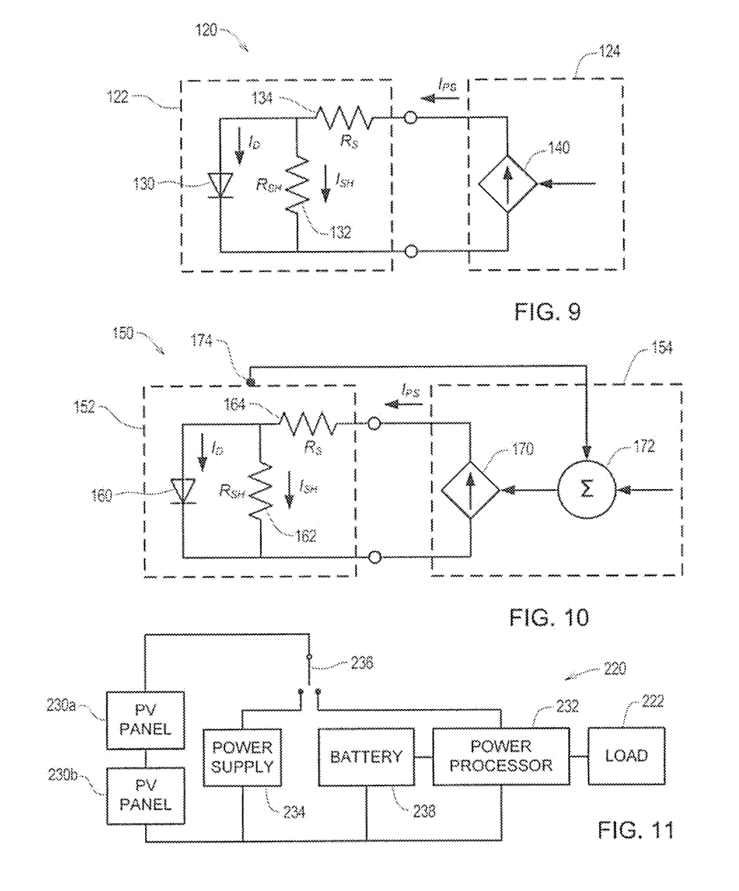

Referring now to FIG. 9 of the drawing, depicted therein is another example solar power system 120 of the present invention. The example solar power system 120 comprises, in addition to a power processor (not shown), a panel 122 and a power supply 124 illustrated in FIG. 8 as an equivalent circuit operating in the heating mode.

The equivalent circuit of the panel 122 comprises a diode 130, a shunt resistance 132, and a series resistance 134. As with the panel 30 described above, current flowing from the power supply 124 (I_{PS}) flows through the series resistance 134 and then divides between the diode 130 (I_{D}) and the shunt resistance 132 (I_{SH}). Again, the current I_{PS} flowing through the series resistance 134 and current I_{SH} flowing through the shunt resistance 132 generate heat.

The example power supply 124 comprises a controlled current source 140. The controlled current source 140 is controlled by a control signal. The control signal can be generated based on environmental factors such as ambient temperature and/or the characteristics of the panel 122. For example, the control signal may be generated based on a lookup table that corresponds control signal values with ambient temperatures. Implemented as shown in FIG. 9, the power supply 124 forms an open loop control system.

Referring now to FIG. 10 of the drawing, depicted therein is another s example solar power system 150 of the present invention. The example solar power system 150 comprises, in addition to a power processor (not shown), a panel 152 and a power supply 154 illustrated in FIG. 9 as an equivalent circuit operating in the heating mode.

The equivalent circuit of the panel 152 comprises a diode 160, a shunt resistance 162, and a series resistance 164. As with the panel 30 described above, current flowing from the power supply 154 (I_{PS}) flows through the series resistance 164 and then divides between the diode 160 (I_{D}) and the shunt resistance 162 (I_{SH}). Again, the current I_{PS} flowing through the series resistance 164 and current I_{SH} flowing through the shunt is resistance 162 generate heat.

The example power supply 154 comprises a controlled current source 170, a summer 172, and a temperature sensor 174. The temperature sensor 174 is configured to generate a temperature signal indicative of a temperature of the panel 152. The summer 172 generates a control signal based on the temperature signal and a reference signal associated with a desired temperature of the panel 152. The example power supply 154 thus forms a closed loop control system that maintains the current I_{PS} such that the temperature of the panel 152 is increased as quickly as possible while maintaining the panel temperature within a desired range selected to inhibit damage to the panel 152.

The solar power system of the present invention may be embodied in many different forms depending upon the requirements of a particular installation.

FIG. 11 illustrates an alternative solar power system 220 adapted to provide power to a load 222. The solar power system 220 comprises two series-connected photovoltaic panels 230a and 230b, a power processor 232, a power supply 234, a switch 236, and a battery 238. The series-connected panels 230a and 230b increase the output voltage of the power system 220. The battery 238 allows the power system 220 to operate in a power generation mode and heating mode as described and also in a standby mode. In the power generation mode, the power processor 232 charges the battery 238; in the standby mode, the power processor 232 generates a power signal based on energy stored in the battery 238. s Optionally, the battery 238 may also be operatively connected to the power supply 234 to supply power to the power supply 234 when the power system 220 operates in the heating mode. In the example solar panel system 220, the output current of the power supply 234 flows through and warms both of the panels 230a and 230b.

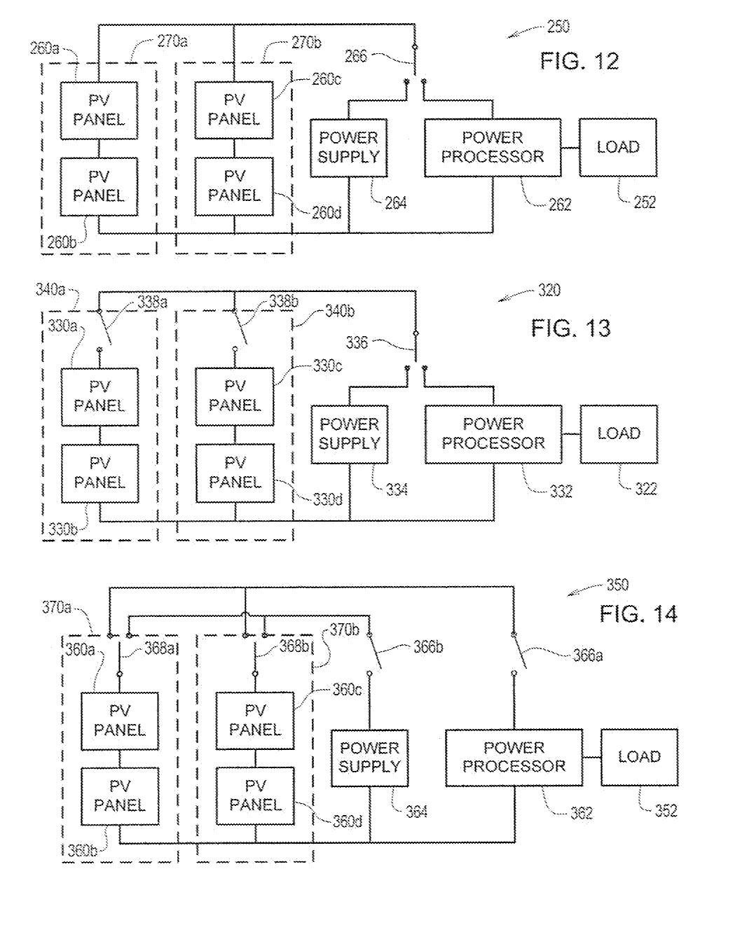

FIG. 12 illustrates a second alternative configuration of a solar power system 250 adapted to provide power to a load 252. The solar power system 250 comprises four photovoltaic panels 260a, 260b, 260c, and 260d, a power processor 262, a power supply 264, and a switch 266. Optionally, a battery may be used as described above. The use of the four is panels 260a-d increases the overall power generating capacity of the power system 250. The panels 260 are arranged in a plurality of panel groups 270a and 270b; each of the example panel groups 270a and 270b comprises a pair of series-connected panels 260a,b and 260c,d, respectively. In the example solar panel system 250, the output current of the power supply 264 flows through and warms all four panels 260a-d simultaneously.

FIG. 13 illustrates a third alternative configuration of a solar power system 320 adapted to provide power to a load 322. The solar power system 320 comprises four photovoltaic panels 330a, 330b, 330c, and 330d, a power processor 332, a power supply 334, a mode select switch 336, and first and second panel group switches 338a and 338b. Optionally, a battery may be used as described above. The panels 330 are arranged in a plurality of panel groups 340a and 340b; each of the example panel groups 340a and 340b comprises a pair of series-connected panels 330a,b and 330c,d, respectively. The panel group switches 338a and 338b are arranged in series with the panels 330a,b and 330c,d of the groups 340a and 340b, respectively. In the example solar panel system 320, the panel group switches 338a and 338b are operated such that the output current of the power supply 334 flows through and warms only one group 340 of the panels 330 at a time. The use of panel group switches reduces the power requirements of the power supply 334.

FIG. 14 illustrates a fourth alternative configuration of a solar power system 350 adapted to provide power to a load 352. The solar power s system 350 comprises four photovoltaic panels 360a, 360b, 360c, and 360d, a power processor 362, a power supply 364, first and second mode select switches 366a and 366b, and first and second panel group switches 368a and 368b. Optionally, a battery may be used as described above. The panels 360 are arranged in a plurality of panel groups 370a and 370b; each of the example panel groups 370a and 370b comprises a pair of series-connected panels 360a,b and 360c,d, respectively. The first and second mode select switches 366a and 366b are arranged in series with the power processor 362 and power supply 364, respectively. The panel group switches 368a and 368b are arranged in series with the panels 360a,b and 360c,d of the groups 370a and 370b, respectively.

In the example solar panel system 350, the panel group switches 368a and 368b are operated such that the output current of the power supply 364 flows through and warms only one group 370 of the panels 360 at a time. In addition, once one of the groups 370 of panels 360 is heated to remove any cold weather related obstruction thereon, energy from the cleared panel group may be applied to the power processor 362.

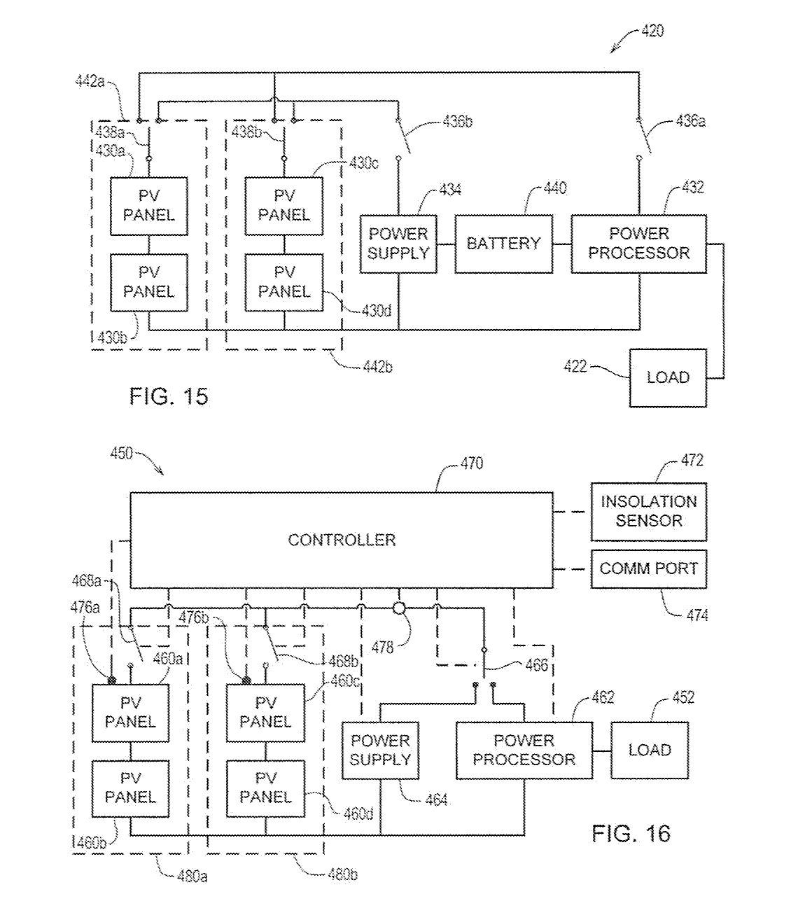

FIG. 15 illustrates a fifth alternative configuration of a solar power system 420 adapted to provide power to a load 422. The solar power system 420 comprises four photovoltaic panels 430a, 430b, 430c, and 430d, a power processor 432, a power supply 434, first and second mode select switches 436a and 436b, and first and second panel group switches 438a and 438b. The example solar power system 420 further comprises a battery 440. The panels 430 are arranged in a plurality of panel groups 442a and 442b; each of the example panel groups 442a and 442b comprises a pair of series-connected panels 430a,b and 430c,d, respectively. The first and second mode select switches 436a and 436b are arranged in series with the power processor 432 and power supply 434, respectively. The panel group switches 438a and 438b are arranged in series with the panels 430a,b and 430c,d of the groups 442a and 442b, respectively.

In the example solar panel system 420, the panel group switches 438a and 438b are operated such that the output current of the power supply 434 flows through and warms only one group 442 of the panels 430 at a time. In addition, once one of the groups 442 of panels 430 is heated to remove any cold weather related obstruction thereon, energy from the cleared panel group may be applied to the power processor 432. Additionally, the battery 440 is operatively connected to both the power processor 432 and the power supply 434 such that the power supply 434 may operate using energy stored in the battery 440.

FIG. 16 illustrates a sixth alternative configuration of a solar power system 450 adapted to provide power to a load 452. The solar power system 450 comprises four photovoltaic panels 460a, 460b, 460c, and 460d, a power processor 462, a power supply 464, a mode select switch 466, and first and second panel group switches 468a and 468b. The example solar power system 450 further comprises a controller 470, an insolation sensor 472, a communications port 474, first and second temperature sensors 476a and 476b, and a current sensor 478. Optionally, a battery may be used as described above.

The panels 460 are arranged in a plurality of panel groups 480a and 480b; each of the example panel groups 480a and 480b comprises a pair of series-connected panels 460a,b and 460c,d, respectively. The panel group switches 468a and 468b are arranged in series with the panels 460a,b and 460c,d of the groups 480a and 480b, respectively. Each of the temperature sensors 476a and 476b are associated with one of the panel groups 480a and 480b, respectively.

In the example solar panel system 450, controller 470 runs an algorithm embodying logic. The algorithm may be implemented in hardware but is likely implemented as a software program running on a general purpose computing device forming part of the controller 470. The controller 470 receives temperature data from the temperature sensors 476a and 476b, insulation data from the insolation sensor 472, weather data received through the communications port 474, and/or output current data from the current sensor 478. Based on the temperature data, insolation data, temperature data, and/or weather data, the controller 470 operates the mode select switch 466 and the panel group switches 468a and 468b to place the system 450 into the power generating mode or the heating mode.

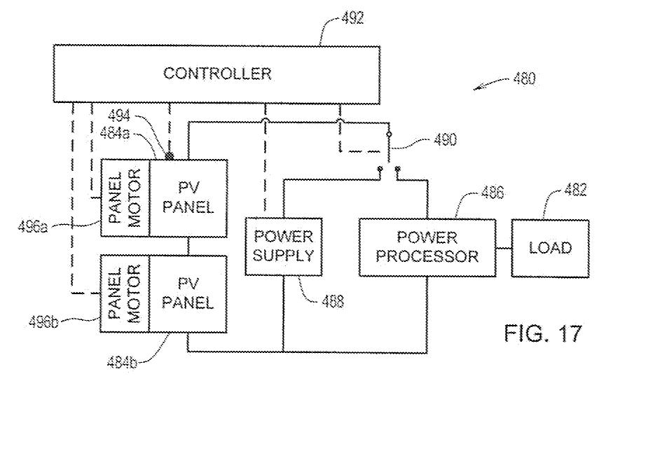

FIG. 17 illustrates a seventh alternative configuration of a solar power system 480 adapted to provide power to a load 482. The solar power system 450 comprises two series-connected photovoltaic panels 484a and 484b, a power processor 486, a power supply 488, and a mode select switch 490. The example solar power system 480 further comprises a controller 492, a temperature sensor 494, and first and second panel motors 496a and 496b associated with the panels 484a and 484b, respectively. Optionally, a battery may be used as described above. The temperature sensor 494 is associated with the panel 484a.

In the example solar panel system 480, the controller 492 runs an algorithm embodying logic. The algorithm may be implemented in hardware but is likely implemented as a software program running on a general purpose computing device forming part of the controller 492. The controller 492 receives temperature data from the temperature sensor 494. Based on the temperature data, the controller 492 operates mode select switch 490 to place the system 480 into the power generating mode or the heating mode.

Additionally, the controller further operates the panel motors 496a and 496b to mechanically clear obstructions from the panels 484a and 484b. The panel motors 496a and 496b can vibrate, tilt, and/or wipe the panels 484a and 484b to clear the obstruction. The mechanical clear operation is typically more effective after the obstruction has been heated.

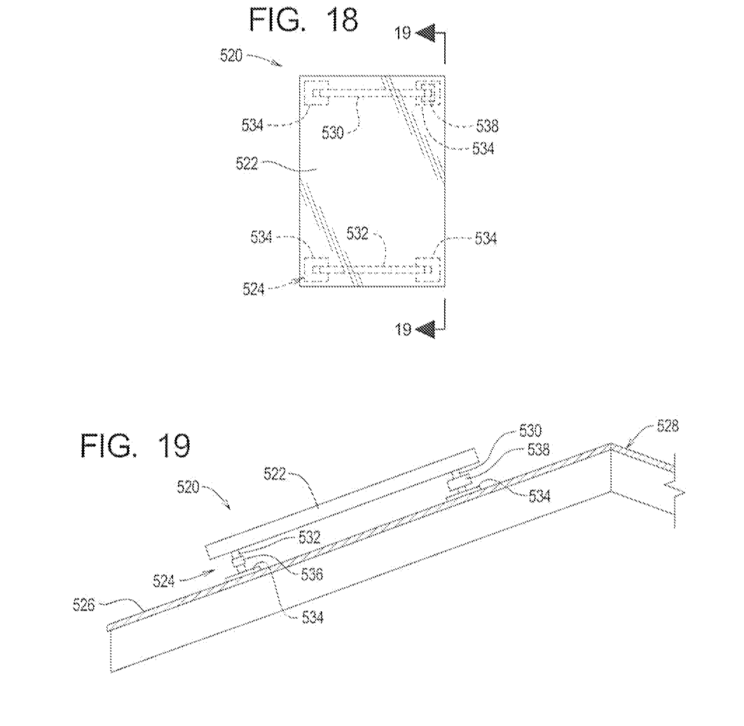

Referring now for a moment to FIGS. 18 and 19, depicted therein is another example solar panel installation 520. The example solar panel installation 520 comprises a single photovoltaic panel 522 for clarity. The photovoltaic panel 522 is supported by a mounting structure 524 on a mounting surface 526 of a structure 528. The example structure 528 is a dwelling, and the example mounting surface 526 is a roof, but the mounting structure 524 may be supported on other mounting surfaces and structures.

As shown in FIGS. 18 and 19, the example mounting structure 524 comprises first and second rails 530 and 532, a plurality of rail brackets 534, a plurality of suspension members 536, and a vibration assembly 538. The rail brackets 534 are rigidly mounted onto the mounting surface 526. The rails 530 and 532 are mounted on the rail brackets 534 by the suspension members 536 and the vibration assembly 538. The rails 530 and 532 support at least one panel 522 but can be scaled to accommodate a plurality of panels.

The vibration assembly 538 contains a panel motor that, when energized, causes the vibration assembly 538 to vibrate. Because the rails 530 and 532 are supported by the vibration assembly 538, the rails 530 and 532 and thus the panel 522 vibrate when the vibration assembly 538 vibrates. The suspension members 536 are resilient and allow slight movement of the rails 530 and 532 relative to the rail brackets 534 and is thus do not interfere with vibration of the panel 522. Operation of the vibration assembly 538 thus can mechanically clear obstructions from the panel 522, especially if the obstruction is heavy snow.

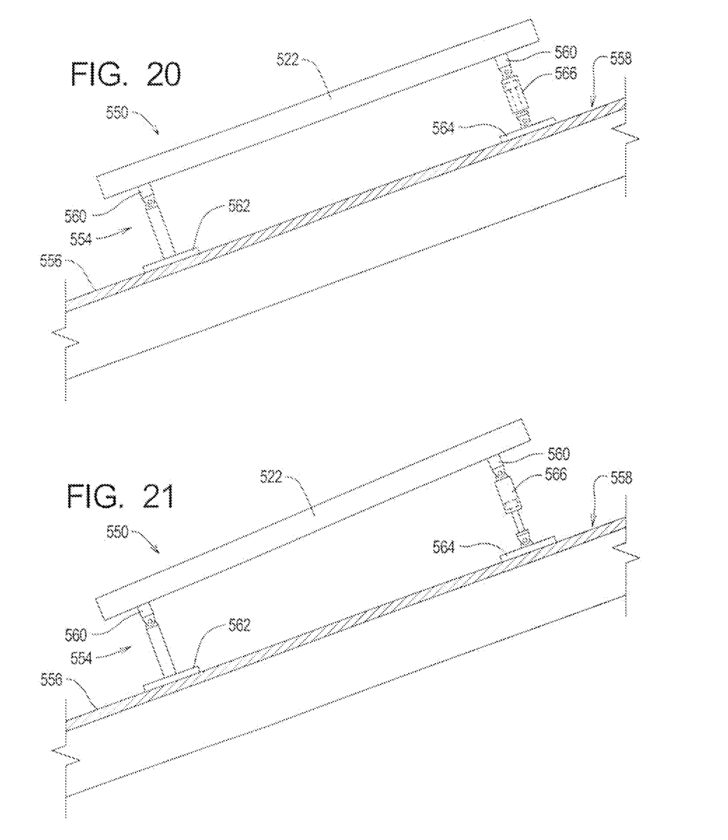

Referring now for a moment to FIGS. 20 and 21, depicted therein is another example solar panel installation 550. Again, the example solar panel installation 550 comprises a single photovoltaic panel 552 for clarity. The photovoltaic panel 552 is supported by a mounting structure 554 on a mounting surface 556 of a structure 558. The example structure 558 is a dwelling, and the example mounting surface 556 is a roof, but the mounting structure 554 may be supported on other mounting surfaces and structures.

As shown in FIGS. 20 and 21, the example mounting structure 554 comprises a plurality of panel brackets 560, a plurality of lower mounting brackets 562, a plurality of upper mounting brackets 564, and at least one actuator assembly 566. The lower mounting brackets 562 are pivotably mounted to the panel brackets 560, while the upper mounting brackets 564 are pivotably connected to the actuator assembly 566. The actuator assembly 566 is in turn pivotably connected to the panel brackets 560. The mounting structure 554 supports at least one panel 552 but can be scaled to accommodate a plurality of panels.

When energized, the actuator assembly 566 extends. Because the panel bracket 560 is supported by the actuator assembly 566, the panel 552 tilts when the actuator assembly 566 extends. Operation of the actuator assembly 566 thus can mechanically clear obstructions from the s panel 552, especially if the obstruction is heavy snow that will slide off of the panel 552 when the panel 552 is tilted.

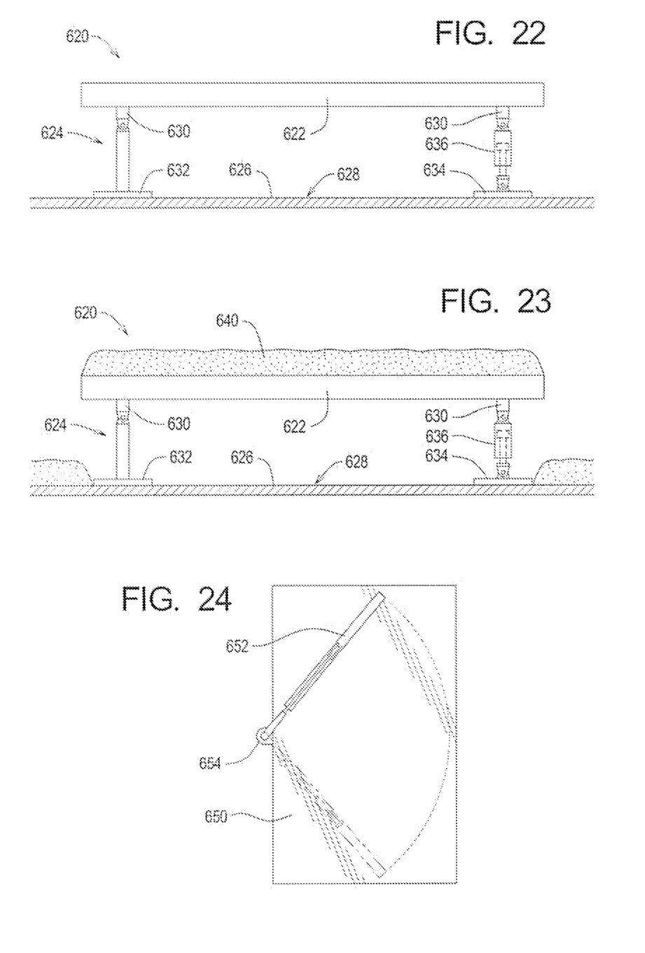

Referring now for a moment to FIGS. 22 and 23, depicted therein is another example solar panel installation 620. Again, the example solar panel installation 620 comprises a single photovoltaic panel 622 for clarity. The photovoltaic panel 622 is supported by a mounting structure 624 on a mounting surface 626 of a structure 628. The example structure 628 is a dwelling, and the example mounting surface 626 is a roof, but the mounting structure 624 may be supported on other mounting surfaces and structures.

As shown in FIGS. 22 and 23, the example mounting structure 624 comprises a plurality of panel brackets 630, a plurality of lower mounting brackets 632, a plurality of upper mounting brackets 634, and at least one weight sensor 636. The lower mounting brackets 632 are pivotably mounted to the panel brackets 630, while the upper mounting brackets 634 are pivotably connected to the weight sensor 636. The weight sensor 636 is in turn pivotably connected to the panel brackets 630. The mounting structure 624 supports at least one panel 622 but can be scaled to accommodate a plurality of panels.

As shown by a comparison of FIGS. 22 and 23, when an obstruction 640 in the form of a snow is on the panel 622, the weight of the panel 622 measured by the weight sensor will include the weight of the obstruction 640. When the weight sensor indicates a weight in a certain range, the obstruction 640 may be effectively removed using a mechanical clear operation.

Referring now to FIG. 24 of the drawing, depicted therein is a panel 650 on which is mounted a wiper blade 652. The wiper blade 652 is supported by a panel motor 654 that, when energized, causes the blade 652 to sweep back and forth across the panel 650. The blade 652 thus mechanically clears an obstruction from the panel 650. Again, the mechanical clear operation conducted by the blade 652 is more effective after the panel 650 has been placed in the heating mode.

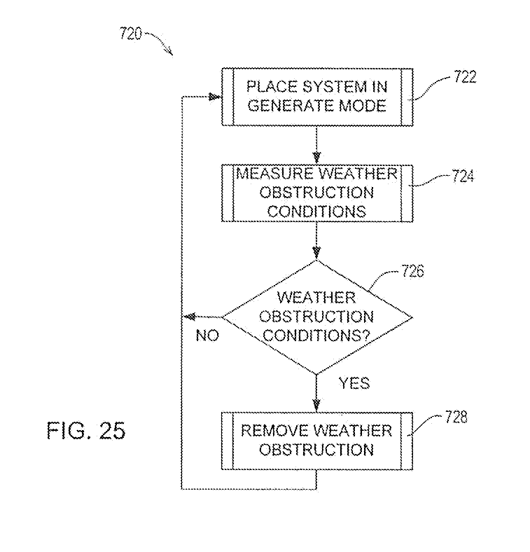

Any of the solar power systems described above may logic in the form of an algorithm to optimize the clearing of obstructions from solar panels. FIGS. 25-31 illustrate a number of example algorithms that may be implemented by the controller of a solar power system of the present invention.

FIG. 25 illustrates a first example algorithm 720 for operating a solar power system of the present invention. The first example algorithm 720 comprises a first step 722 in which the solar panel system is placed in the power generation mode. Operating conditions indicative of an obstruction are monitored at step 724. Example operating conditions that may be indicative of an obstruction include air or photovoltaic panel temperature, insolation level, output voltage and current of the solar panel, weather conditions, and weight on the solar panel. At step 726, it is determined whether the operating conditions indicate that an obstruction is present on the panel. If not, the algorithm 720 returns to the first step 722 and stays in the power generation mode.

If the operating conditions indicate that an obstruction is present on the panel, the obstruction is removed at step 728. Removal of the obstruction may be accomplished by any one or more of the following procedures: placing the solar power system in the heating mode; and performing a mechanical clear of the panel.

The algorithm 720 may run continuously, may run at preset intervals, or may run asynchronously based on the occurrence of events such as sunrise, change in temperature, external command, or the like.

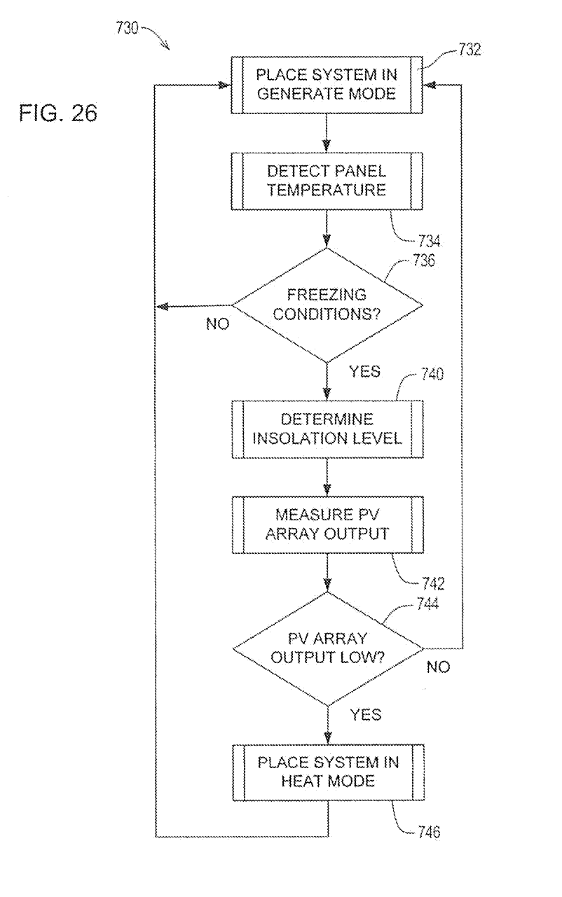

A second example algorithm 730 for operating a solar power system of the present invention is depicted in FIG. 26. The second example algorithm comprises a first step 732 in which the solar panel system is placed in the power generation mode. The temperature of the panel is detected at step 734. At step 736, the algorithm 730 determines whether freezing conditions are present. If not, the algorithm 730 returns to step 732 and the system remains in the power generation mode.

If step 736 determines that freezing conditions indicative of a possible obstruction exist, the algorithm 730 proceeds to step 740 and determines the insolation level. At step 742, the algorithm 730 measures the output of the array of photovoltaic panels. If the output of the photovoltaic panels is within a predicted range associated with the insolation level, step 744 determines that the photovoltaic array output is not low and returns to step 732, where the system remains in the power generation mode.

If, on the other hand, the algorithm 730 determines that the output of the photovoltaic array is low at step 744, the algorithm 730 proceeds to step 746, at which the system is placed in the heating mode. Once the system is in the heating mode, the algorithm 730 can maintain the system in the heating mode for a predetermined period of time. Alternatively, the algorithm 730 may maintain the system in the heating mode for a variable period of time determined by factors such as the panel temperature. After is some time, the algorithm 730 returns to step 740 and returns the system in the power generation mode.

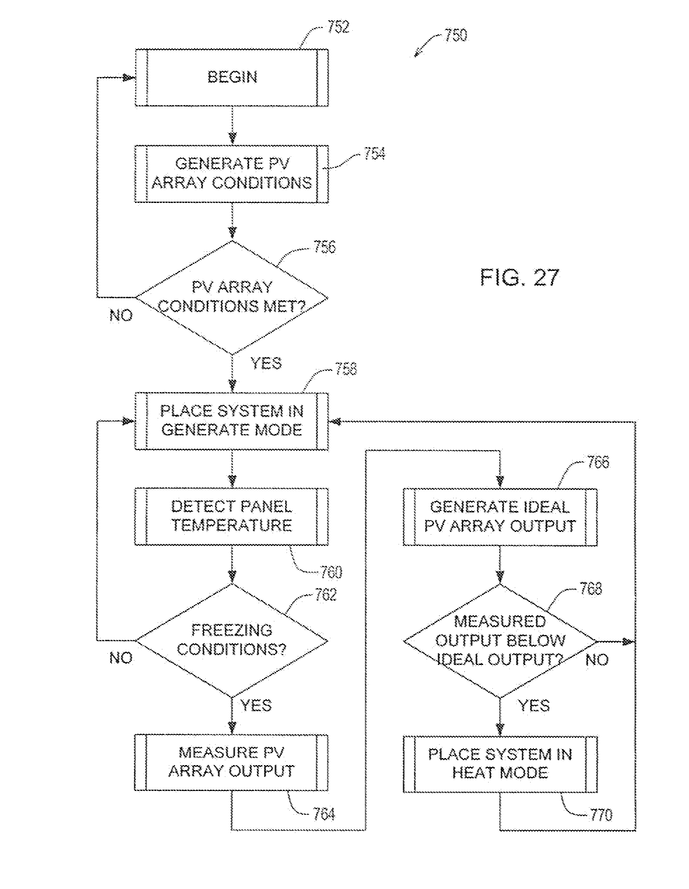

The algorithm 730 may run continuously, may run at preset intervals, or may run asynchronously based on the occurrence of events such as sunrise, change in temperature, external command, or the like. A third example algorithm 750 for operating a solar power system of the present invention is depicted in FIG. 27. The third example algorithm 750 comprises a first step 752 in which the algorithm begins. At step 754, the algorithm gathers data associated with PV Array conditions that determine whether the photovoltaic array is capable of operating. For example, the PV Array conditions may indicate that it is night time. Step 756 determines whether the PV Array conditions are met. If the PV Array conditions are not met, the algorithm returns to step 752.

If the PV Array conditions are met, the algorithm 750 proceeds to step 758, at which the system operates in the generate mode. The temperature of the panel is detected at step 760. At step 762, the algorithm 750 determines whether freezing conditions are present. If not, the algorithm 750 returns to step 758 and the system remains in the power generation mode.

If step 762 determines that freezing conditions indicative of a possible obstruction exist, the algorithm 750 proceeds to step 764, at which the output of the photovoltaic array is measured, and then to step 766, at which the ideal photovoltaic array output is generated. The algorithm 750 then proceeds to stop 768, where the actual output of the photovoltaic array is measured. If the measured output of the photovoltaic array is not less than the ideal photovoltaic array output, the system returns to step 758 and the system remains in the power generation mode.

If the measured output of the photovoltaic array is less than the ideal photovoltaic array output, the algorithm 750 proceeds to step 770, at which the system is placed in the heating mode. Once the system is in the heating mode, the algorithm 750 can maintain the system in the heating mode for a predetermined period of time. Alternatively, the algorithm 750 may maintain the system in the heating mode for a variable period of time determined by factors such as the panel temperature. After some time, the algorithm 750 returns to step 758 and returns the system in the power generation mode.

Like the algorithms 720 and 730, the algorithm 750 may run continuously, may run at preset intervals, or may run asynchronously based on the occurrence of events such as sunrise, change in temperature, external command, or the like.

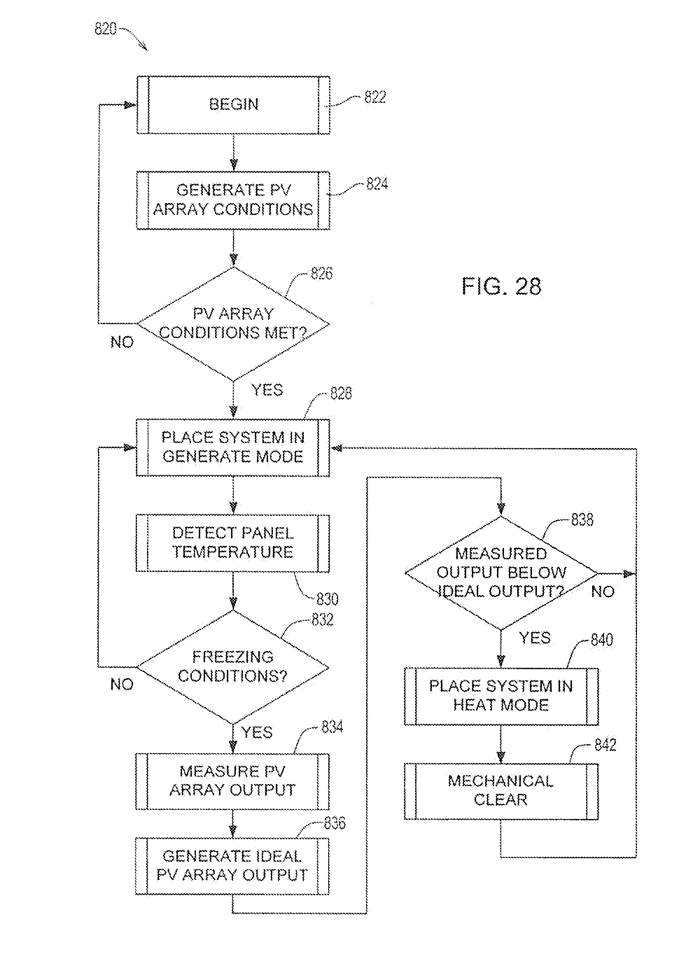

A fourth example algorithm 820 for operating a solar power system of the present invention is depicted in FIG. 28. The fourth example algorithm 820 comprises a first step 822 in which the algorithm begins. At step 824, the algorithm gathers data associated with PV Array conditions that determine whether the photovoltaic array is capable of operating. For example, the PV Array conditions may indicate that it is night time. Step 826 determines whether the PV Array conditions are met. If the PV Array conditions are not met, the algorithm returns to step 822.

If the PV Array conditions are met, the algorithm 820 proceeds to step 828, at which the system operates in the generate mode. The temperature of the panel is detected at step 830. At step 832, the algorithm 820 determines whether freezing conditions are present. If not, the algorithm 820 returns to step 828 and the system remains in the power generation mode.

If step 832 determines that freezing conditions indicative of a possible obstruction exist, the algorithm 820 proceeds to step 834, at which the output of the photovoltaic array is measured, and then to step 836, at which the ideal photovoltaic array output is generated. The algorithm 820 then proceeds to stop 838, where the actual output of the photovoltaic array is measured. If the measured output of the photovoltaic array is not less than the ideal photovoltaic array output, the system returns to step 828 and the system remains in the power generation mode.

If the measured output of the photovoltaic array is less than the ideal photovoltaic array output, the algorithm 820 proceeds to step 840, at which the system is placed in the heating mode. Once the system is in the heating mode, the algorithm 820 can maintain the system in the heating mode for a predetermined period of time. Alternatively, the algorithm 820 may maintain the system in the heating mode for a variable period of time is determined by factors such as the panel temperature.

After some time, the algorithm 820 proceeds to step 842 at which a mechanical clear procedure is executed. After the mechanical clear procedure is completed, the algorithm proceeds to step 828 and returns the system in the power generation mode.

Like the algorithms 720, 730, and 750, the algorithm 820 may run continuously, may run at preset intervals, or may run asynchronously based on the occurrence of events such as sunrise, change in temperature, external command, or the like.

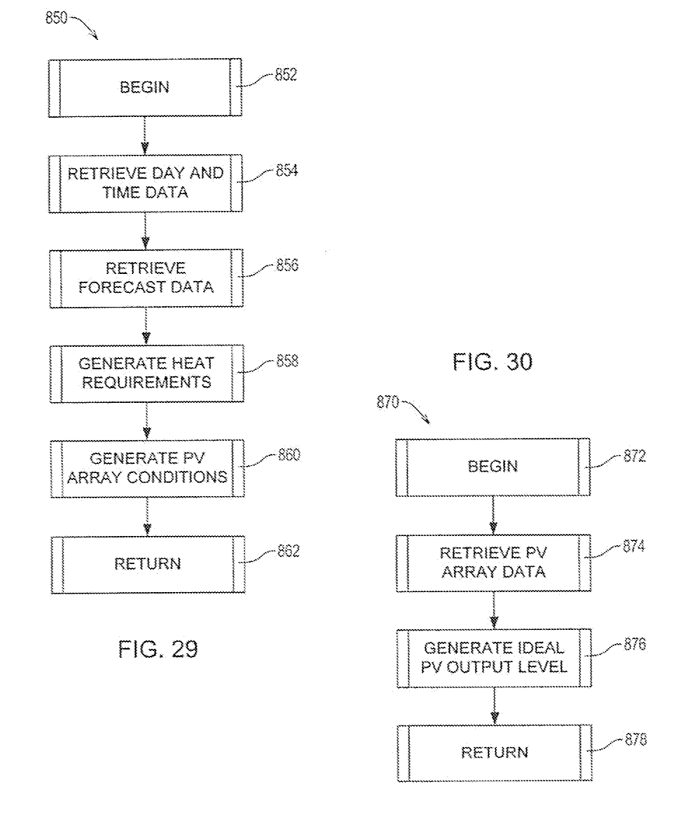

Turning now to FIG. 29, depicted therein is a procedure 850 that may be executed when the algorithms 730, 750, and 820 perform the step of generating PV Array conditions. The procedure begins at step 852; at step 856, the procedure retrieves day and time data to determine. At step 854, the procedure retrieves forecast data. At step 858, the procedure 850 calculates the predicted amount of required to remove the obstruction from the solar panel. Based on the data collected and/or calculated in steps 854, 856, and 858, procedure 850 generates a number or set of numbers representative of the photovoltaic array conditions at step 860. At step 862, the procedure returns to the main algorithm.

FIG. 30 illustrates a procedure 870 for executing the step of generating the ideal PV Array Output data in algorithms 750 and 820 above. The procedure 870 begins at step 872 and proceeds to step 874, where data relating to the particular photovoltaic array such as panel size, number of panels, and efficiency rating of the panels is retrieved. Based on this data, the ideal PV Output level for the particular solar panel system is calculated at step 876. The ideal PV Output level may further take into considerations such as insolation levels and the like. At step 878, the procedure 870 returns to the main algorithm.

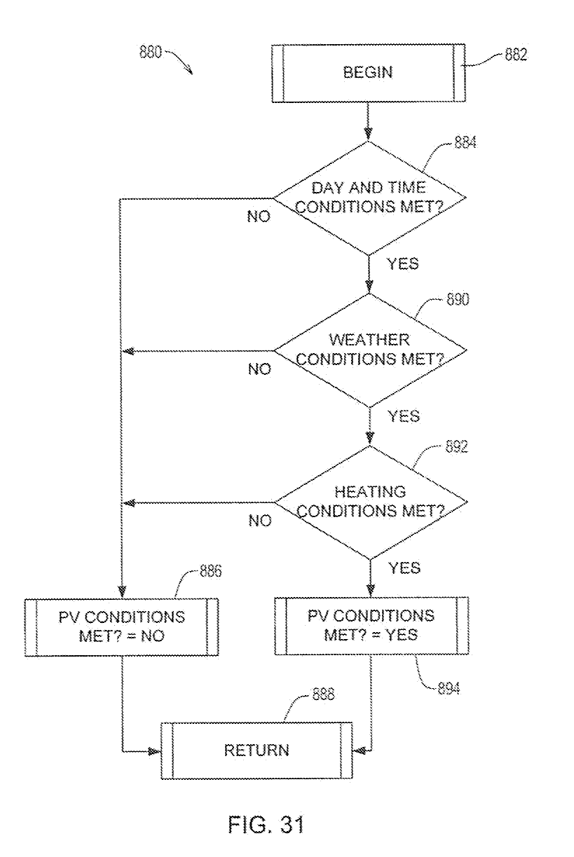

FIG. 31 illustrates an example procedure 880 for executing the step of determining whether PV Array conditions are met in the algorithms 730, 750, and 820. The procedure begins at step 882. At step 884, the procedure determines whether day and time conditions are met. If not, the procedure proceeds to step 886, which changes the PV Conditions variable to “no”. The procedure then proceeds to step 888, which returns the PV Conditions variable to the main algorithm.

If the day and time conditions are met, the procedure proceeds to step 890, which determines whether weather conditions are met. If not, the procedure proceeds to step 886, and the PV Conditions variable is set to “no”.

If the weather conditions are met, the procedure proceeds to step 892, which determines whether heating conditions are met. If not, the procedure proceeds to step 886, and the PV Conditions variable is set to “no”.

If the heating conditions are met, the procedure proceeds to step 894, which sets the PC Conditions variable to “yes”. The procedure then proceeds to step 888, which returns the PV Conditions variable to the main algorithm.

Given the foregoing, it should be apparent that the present invention may be embodied in forms other than those above. The scope of the present invention should thus be determined by the following claims and not the foregoing description of examples of the invention.

What is claimed is:

1. A solar power system for supplying electrical energy to a load based on solar energy comprising:
at least one solar panel comprising at least one solar cell;
a power supply; and
at least one mode select switch operatively connected to the at least one solar panel, the power supply, and the load, where the at least one mode select switch is operable in
a first mode in which the at least one solar cell is capable of supplying electrical energy to the load; and
a second mode in which the power supply supplies electrical energy to the at least one solar cell such that the at least one solar cell generates heat.

2. A solar power system as recited in claim 1, further comprising a power processor, where the power processor operatively connects the at least one solar cell to the load when the at least one mode select switch operates in the first mode.

3. A solar power system as recited in claim 1, in which the at least one solar cell comprises at least one resistive element, where the power supply causes current to flow through the at least one resistive element when the at least one mode select switch operates in the second mode.

4. A solar power system as recited in claim 1, in which, when the at least one mode select switch operates in the second mode, the power supply supplies electrical energy to the at least one solar cell based at least in part on a reference signal.

5. A solar power system as recited in claim 1, further comprising a temperature sensor for generating temperature data indicative of a temperature of the at least one solar panel, where, when the at least one mode select switch operates in the second mode, the power supply supplies electrical energy to the at least one solar cell based at least in part on the temperature data.

6. A solar power system as recited in claim 1, further comprising a temperature sensor for generating temperature data indicative of a temperature of the at least one solar panel, where, when the at least one mode select switch operates in the second mode, the power supply supplies electrical energy to the at least one solar cell based at least in part on the temperature data.

7. A solar power system as recited in claim 1, further comprising an insolation sensor for generating insolation data indicative of an insolation level associated with the at least one solar panel, where the power supply supplies electrical energy to the at least one solar cell based at least in part on the insolation data.

8. A solar power system as recited in claim 1, further comprising
a temperature sensor for generating temperature data indicative of a temperature of the at least one solar panel; and
an insolation sensor for generating insolation data indicative of an insolation level associated with the at least one solar panel; wherein
the power supply supplies electrical energy to the at least one solar cell based at least in part on the temperature data and the insolation data.

9. A solar power system as recited in claim 1, further comprising:
a plurality of panel groups each comprising at least one solar panel; and
a panel group switch associated with each of the plurality of panel groups; wherein
when the at least one mode select switch operates in the second mode, the panel group switches are operable to allow electrical energy to be supplied to the at least one solar panel in a selected one of the panel groups.

10. A solar power system as recited in claim 1, further comprising an energy storage device, wherein:
when the at least one mode select switch operates in the first mode, the solar power system is capable of supplying electrical energy to the load at least in part based on the energy stored in the energy storage device; and
when the at least one mode select switch operates in the second mode, the solar power system is capable of supplying electrical energy to the load at least in part based on the energy stored in the energy storage device.

11. A solar power system as recited in claim 10, in which, when the at least one mode select switch operates in the first mode, the at least one solar cell is capable of supplying electrical energy to the energy storage device.

12. A solar power system as recited in claim 1, further comprising a transducer for moving the at least one solar panel.

13. A solar power system as recited in claim 12, in which the transducer causes the at least one solar panel to vibrate.

14. A solar power system as recited in claim 12, in which the transducer causes the at least one solar panel to tilt.

15. A method of supplying electrical energy to a load based on solar energy comprising the steps of:
providing at least one solar panel comprising at least one solar cell;
providing a power supply; and
operatively connecting at least one mode select switch to the at least one solar panel, the power supply, and the load;
operating the at least one mode select switch in a first mode in which the at least one solar cell is capable of supplying electrical energy to the load; and
operating the at least one mode select switch in a second mode in which the power supply supplies electrical energy to the at least one solar cell such that the at least one solar cell generates heat.

16. A method as recited in claim 15, further comprising the steps of:
generating temperature data indicative of a temperature of the at least one solar panel; and
supplying electrical energy to the at least one solar cell based at least in part on the temperature data when the at least one mode select switch operates in the second mode.

17. A method as recited in claim 15, further comprising the steps of:
generating insolation data indicative of an insolation level associated with the at least one solar panel; and
supplying electrical energy to the at least one solar cell based at least in part on the insolation data when the at least one mode select switch operates in the second mode.

18. A method as recited in claim 15, further comprising the step of moving the at least one solar panel.

19. A solar power system for supplying electrical energy to a load based on solar energy comprising:
at least one solar panel comprising at least one solar cell, where the solar cell comprises at least one resistive element;
a temperature sensor for generating temperature data indicative of a temperature of the at least one solar panel; and
an insolation sensor for generating insolation data indicative of an insolation level associated with the at least one solar panel; and
a current supply; and
at least one mode select switch operatively connected to the at least one solar panel, the current supply, and the load, where the at least one mode select switch is operable in
a first mode in which the at least one solar cell is capable of to supplying electrical energy to the load; and
a second mode in which the current supply supplies current to the at least one resistive element of the at least one solar cell at least in part on the temperature data and the insolation data such that the at least one solar cell generates heat.

20. A solar power system as recited in claim 19, further comprising a transducer for moving the at least one solar panel.
